(19) United States
(12) Patent Application Publication
(10) Pub. No.: US 2024/0006856 A1
(43) Pub. Date: Jan. 4, 2024

(54) Semiconductor Structure and Semiconductor Device

(71) Applicant: Nippon Telegraph and Telephone Corporation, Tokyo (JP)

(72) Inventors: Wataru Kobayashi, Tokyo (JP); Shigeru Kanazawa, Tokyo (JP); Takahiko Shindo, Tokyo (JP)

(21) Appl. No.: 18/251,925

(22) PCT Filed: Nov. 25, 2020
(86) PCT No.: PCT/JP2020/043785

§ 371 Date: May 5, 2023

(51) Int. Cl. H01S 5/343

(52) U.S. Cl. CPC H01S 5/34373

(57) ABSTRACT

A semiconductor structure includes InP as a substrate and includes, in order, a multi-quantum well, an anti-diffusion layer, and a p-type InP layer doped with Zn. The anti-diffusion layer includes a plurality of layers that substantially lattice-match InP, and at least one layer among the plurality of layers contains Al, In, and As and is doped with carbon.

### CROSS-REFERENCE TO RELATED APPLICATIONS

This patent application is a national phase filing under section 371 of PCT application no. PCT/JP2020/043785, filed on Nov. 25, 2020, which application is incorporated herein by reference in its entirety.

### TECHNICAL FIELD

The present invention relates to a semiconductor structure and a semiconductor element including a Zn-doped p-type layer.

### BACKGROUND

Semiconductor modulators that convert electric signals into optical signals have widely been used with an increase in capacity of optical communication. In particular, electroabsorption (EA) modulators have been required because of their small sizes and low power consumption.

In EA modulators using long-wavelength band InP-based semiconductors that are compatible with optical communication, Zn, which is a p-type dopant, diffuses in multi-quantum wells (MQWs) and degrades extinction properties of the EA modulators.

In relation to curbing of Zn diffusion, a technique of curbing mutual diffusion of Fe and Zn, which are dopants, in buried semi-insulating layers of the EA modulators has been reported.

### CITATION LIST

### Non Patent Literature

Non Patent Literature 1: T. Yamanaka et al., “Influence of Zn diffusion on bandwidth and extinction in MQW electroabsorption modulators buried with semi-insulating InP,” 8th Opto-Electronics and Communications Conf. (OECC2003), Proc., pp. 439-440, 2003.

### SUMMARY

### Technical Problem

However, a conventional EA modulator is configured of a cladding layer doped with Zn 65, a contact layer 64, an undoped multi-quantum well structure (i-MQW) 62, and an Si-doped n-InP substrate 61 as illustrated in FIG. 10. In this configuration, Zn, which is a dopant of p, diffuses from the cladding layer to the i-MQW and degrades an extinction property of the EA modulator, which has been problematic.

### Solution to Problem

In order to solve the aforementioned problem, a semiconductor structure according to embodiments of the present invention is a semiconductor substrate including InP as a substrate and including, in order: a multi-quantum well; an anti-diffusion layer, and a p-type InP layer, in which the p-type InP layer is doped with Zn, the anti-diffusion layer includes a plurality of layers, the plurality of layers substantially lattice-match InP, and at least one layer among the plurality of layers contains Al, In, and As and is doped with carbon.

### Advantageous Effects of Embodiments of the Invention

According to embodiments of the present invention, it is possible to provide a high-performance semiconductor structure and a semiconductor element capable of reducing an influence of Zn diffusion.

### BRIEF DESCRIPTION OF THE DRAWINGS

FIG. 1 is a schematic sectional view illustrating a semiconductor structure according to a first embodiment of the present invention.

FIG. 2 is a diagram for explaining a semiconductor element according to the first embodiment of the present invention.

FIG. 3A is a diagram illustrating Zn concentration depth-direction distribution in the semiconductor structure according to the first embodiment of the present invention.

FIG. 3B is a diagram illustrating Zn concentration depth-direction distribution in a conventional semiconductor structure.

FIG. 4A is a light intensity distribution diagram in the semiconductor structure according to the first embodiment of the present invention.

FIG. 4B is a light intensity distribution diagram in the conventional semiconductor structure.

FIG. 5 is a diagram for explaining light trapping in the semiconductor structure according to the first embodiment of the present invention.

FIG. 6 is a schematic sectional view (front) of a semiconductor element in Example 1 of embodiments of the present invention.

FIG. 7 is a schematic sectional view of a semiconductor structure in Example 1 of embodiments of the present invention.

FIG. 8 is a diagram illustrating a property of the semiconductor element according to Example 1 of embodiments of the present invention.

FIG. 9 is a schematic sectional view of a semiconductor structure according to Example 2 of embodiments of the present invention.

FIG. 10 is a schematic sectional view of the conventional semiconductor structure.

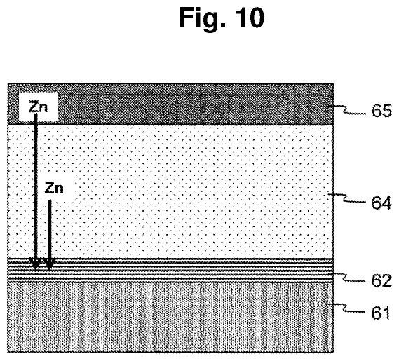

### DETAILED DESCRIPTION OF ILLUSTRATIVE EMBODIMENTS

### First Embodiment

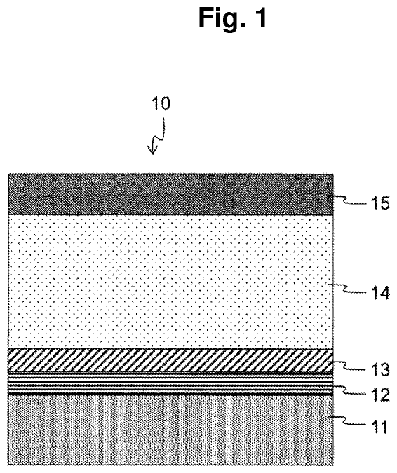

A semiconductor structure according to a first embodiment of the present invention will be described with reference to FIGS. 1 to 5.

### Configuration of Semiconductor Structure

FIG. 1 illustrates a semiconductor structure 10 for an optical modulator according to the present embodiment. The semiconductor structure 10 includes, in order, an n-type InP substrate 11, a multi-quantum well (MQW) 12, an anti-diffusion layer 13, a p-type InP cladding layer 14, and a p-type InGaAs contact layer 15.

The MQW 12 includes eight InGaAlAs well layers (amount of strain: −0.5%, layer thickness: 10 nm) and nine InGaAlAs barrier layers (amount of strain: +0.3%, layer thickness: 6 nm), and the photoluminescence (PL) wavelength is 1.23 μm.

The anti-diffusion layer 13 has a laminated structure of carbon(C)-doped InAlAs and carbon (C)-doped InGaAlAs. Specifically, seven InGaAlAs well layers (amount of strain: −0.5%, and layer thickness: 10 nm) and eight InGaAlAs barrier layers (amount of strain: +0.3%, layer thickness: 6 nm) are alternately laminated, for example. Also, the carbon (C) doping concentration is 3×10¹⁷ cm⁻³.

The thickness of the p-type InP cladding layer 14 is 1500 nm. Also, Zn is used as a p-type dopant, and the Zn doping concentration is 1×10¹⁸ cm⁻³.

The thickness of the p-type InGaAs contact layer 15 is 500 nm. Also, Zn is used as a p-type dopant, and the Zn doping concentration is 3 to 5×10¹⁸ cm⁻³.

The semiconductor structure 10 is made to experience crystal growth by ordinary MOVPE. In crystal growth of the anti-diffusion layer, in particular, it is possible to use trimethylindium (TMIn), triethylgallium (TEGa), or trimethylaluminum (TMAl) as a group III raw material and phosphine (PH₃) or arsine (AsH₃) as a group V raw material gas. For the carbon (C) doping, CBr₄ is used as a raw material. The crystal growth temperature is 600° C.

The anti-diffusion layer 13 will be described. In an ordinary semiconductor structure, diffusion of Zn to the MQW can be curbed by inserting a thick intrinsic (i)-type InP layer between the p-type InP layer and the MQW layer. Here, it is possible to use an undoped (doping is not performed thereon) InP layer or a ruthenium (Ru)-doped semi-insulating InP layer, for example, as the i layer. However, an increase in thickness of the i layer leads to an increase in device resistance, which may cause a problem.

Thus, a laminated structure of C-doped InAlAs and InGaAlAs is used for the anti-diffusion layer. In InAlAs and InGaAlAs, carbon (C) serves as a p-type dopant (K. Kurihara et al., 1.3-μm Laser diode with a high-quality C-doped InAlAs, IPRM 2004, TuB1-3). As a result, it is possible to curb an increase in device resistance caused by insertion of the anti-diffusion layer.

Moreover, the p-type dopant C has a small diffusion coefficient. Therefore, the p-type dopant substantially does not diffuse to the MQW, and it is thus possible to curb degradation of a device property due to the p-type dopant (impurity).

In this manner, the p-doped InGaAlAs and InAlAs can prevent Zn diffusion without increasing the device resistance.

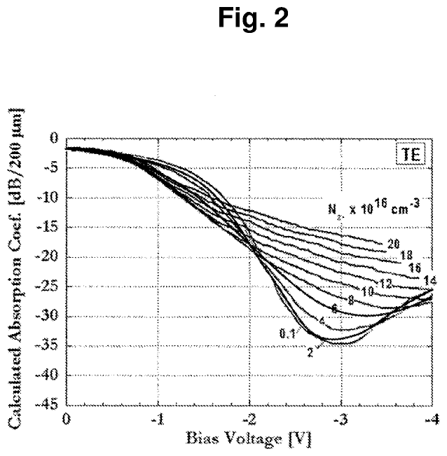

FIG. 2 illustrates a calculation result in relation to dependency of an extinction property of the EA modulator on the carrier (Zn) concentration in the MQW. The calculation is performed by calculating an overlap integral of wave functions of electrons and holes in the quantum well and obtaining vibrator strength.

In the EA modulator, the amount of extinction with respect to voltage application decreases and the extinction property is degraded as the carrier (Zn) in the i-MQW increases. Specifically, when the concentration of diffusion of Zn to i-MQW is equal to or greater than 4×10¹⁶ cm⁻³, a change (extinction curve) in ratio of extinction due to voltage application is mild, and a steep extinction curve is not obtained. On the other hand, when the concentration of diffusion of Zn to the i-MQW is equal to or less than 2×10¹⁶ cm⁻³, a steep extinction curve due to voltage application is obtained.

It is possible to ascertain from the above that it is necessary to reduce the carrier (Zn) concentration in the i-MQW, that is, the concentration of diffusion of Zn to the i-MQW to be equal to or less than 2×10¹⁶ cm⁻³.

### Effects of Semiconductor Structure

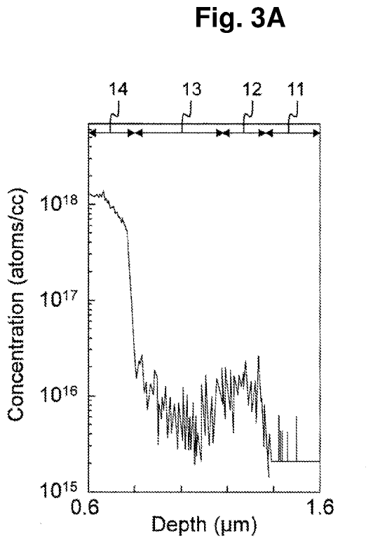

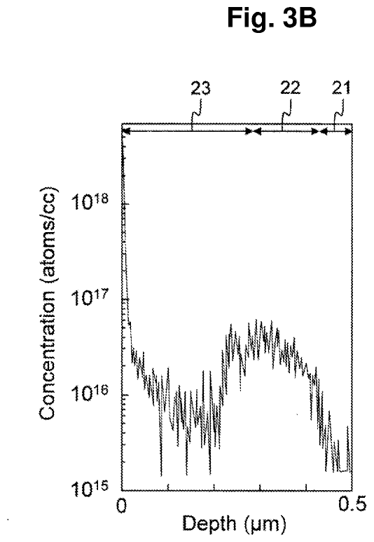

FIG. 3A illustrates Zn concentration in the semiconductor structure according to this embodiment of the present invention. The Zn concentration is measured by SIMS. FIG. 3A illustrates, in order, Zn concentration in the p-type cladding layer 14, the anti-diffusion layer 13, the MQW 12, and the substrate 11 from the depth of 0.6 μm from the surface of the sample. The Zn doping concentration in the p-type cladding layer 14 is about 1×10¹⁸ cm⁻³.

The structure of the anti-diffusion layer 13 has a laminated structure of carbon (C)-doped InAlAs and carbon (C)-doped InGaAlAs. Specifically, seven InGaAlAs well layers (amount of strain: −0.5%, and layer thickness: 10 nm) and eight InGaAlAs barrier layers (amount of strain: +0.3%, layer thickness: 6 nm) are alternately laminated, for example. Also, the carbon (C) doping concentration is 3×10¹⁷ cm⁻³.

In the semiconductor structure, the Zn concentration decreases from the concentration of about 10¹⁸ cm⁻³ to the concentration of equal to or less than 10¹⁶ cm⁻³ in the anti-diffusion layer 13. As a result, the Zn concentration in the MQW 12 is 10¹⁶ cm⁻³ and can be reduced to be equal to or less than 2×10¹⁶ cm⁻³.

FIG. 3B illustrates the Zn concentration in a semiconductor structure that does not include the anti-diffusion layer 13 as a comparative example. The sample in the comparative example is provided with an undoped (not doped with Zn) InP layer 23 instead of the anti-diffusion layer 13. As a sample used in SIMS measurement, a sample obtained by removing the p-type cladding layer (Zn doping concentration: about 10¹⁸ cm⁻³) through etching is used. The Zn concentration represented as high concentration when the depth is 0 μm in FIG. 3B indicates an influence of the remaining part of the layer when a part of the p-InP layer is removed by etching at the time of producing the sample for SIMS measurement.

In the comparative example, the Zn concentration is reduced to a concentration of equal to or less than 10¹⁶ cm⁻³ in the InP layer 23 while the Zn concentration in the MQW 22 is 5×10¹⁶ cm⁻³. As described above, the Zn concentration in the MQW 22 is not reduced to the concentration of equal to or less than 2×10¹⁶ cm⁻³ regardless of the undoped InP layer 23 provided between the p-type cladding layer 24 and the MQW 22 in the comparative example.

The above result indicates that it is possible to curb the Zn concentration in the MQW to the concentration of equal to or less than 2×10¹⁶ cm⁻³ and thereby to curb degradation of the property of the EA modulator by the anti-diffusion layer.

Here, the effect of preventing Zn diffusion can be achieved by using the laminated structure including layers of a plurality of compositions as the laminated structure of InAlAs and InGaAlAs in the present embodiment for the anti-diffusion layer 13 as compared with an InAlAs or InGaAlAs layer of a single composition. This is considered to be because diffusing Zn is trapped at boundaries (heterointerfaces) of the layers of different compositions in the laminated structure.

In addition, although the example in which the layer thickness of the anti-diffusion layer 13 is set to 400 nm has been described in the present embodiment, the effect is achieved by the layer thickness of equal to or greater than 50 nm.

Next, light trapping in the semiconductor structure according to the present embodiment will be described.

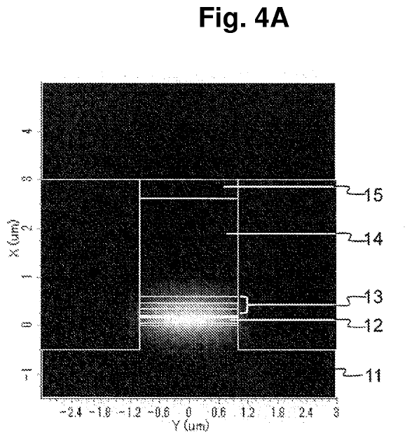

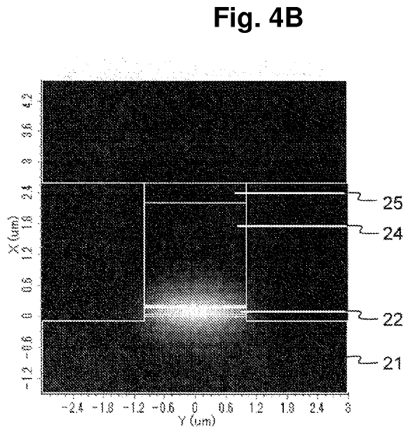

FIG. 4A illustrates light intensity distribution in the semiconductor structure according to the present embodiment. Calculation was performed using simulation software “APSS” (version 2.3 g manufactured by Apollo).

As the semiconductor structure, a layer structure including, in order, a substrate 11, an MQW 12, an anti-diffusion layer 13, a cladding layer 14, and a contact layer 15 was used. The semiconductor structure as a waveguide structure with a width of 2 μm and with the periphery thereof covered with InP was used as a calculation target. The wavelength of guided light in the calculation was 1.30 μm.

Here, a laminated structure of InAlAs and InGaAlAs (bandgap wavelength: 1.0 μm) was used for the anti-diffusion layer 13. The layer thickness of the entire laminated structure was about 300 nm, and the ratio between the total layer thickness of InAlAs and the total layer thickness of InGaAlAs was set to 1:1. Specifically, the anti-diffusion layer 13 includes layers in which InAlAs (thickness of 5 nm) and InGaAlAs (thickness of 5 nm) were alternately laminated and includes layers configured of thirty one InAlAs layers and thirty InGaAlAs layers.

Also, FIG. 4B illustrates light intensity distribution in a semiconductor structure that does not include an anti-diffusion layer as a comparative example. The semiconductor structure in the comparative example has a layer structure including, in order, a substrate 21, an MQW 22, a cladding layer 24, and a contact layer 25.

Here, the white lines in FIGS. 4A and 4B indicate the semiconductor structures as targets of calculation. Also, the white display indicates high light intensity while the black display indicates low light intensity, in regard to the light intensity in the drawing.

In the light intensity distribution in the comparative example, guided light is distributed around the MQW 22, and high light intensity is shown in the MQW 22. In this manner, strong light trapping is shown in the MQW 22.

On the other hand, in the semiconductor structure according to the present embodiment, guided light is distributed around the MQW 12, high light intensity is shown in the MQW 12, and high light intensity is also shown in a part of the anti-diffusion layer 13. In this manner, a trend that a part of the guided light in the MQW 12 leaks to the anti-diffusion layer 13 is shown in the semiconductor structure.

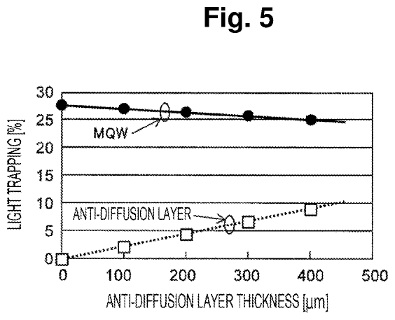

Next, light trapping in the semiconductor structure according to the present embodiment will be quantitatively explained. FIG. 5 illustrates dependency of light trapping in the MQW 12 and the anti-diffusion layer 13 on the thickness of the anti-diffusion layer. The calculation was performed similarly to the above method. Here, the thickness of the anti-diffusion layer 13 was changed such that the ratio between the total layer thickness of InAlAs and the total layer thickness of InGaAlAs was 1:1.

The light trapping in the MQW 12 decreases as the thickness of the anti-diffusion layer 13 increases (the block circles and solid lines in the drawing). On the other hand, light trapping in the anti-diffusion layer 13 increases as the thickness of the anti-diffusion layer 13 increases (white squares and dotted lines in the drawing). When the thickness of the anti-diffusion layer 13 is 400 nm, the light trapping in the MQW 12 is 25%, which is lower than the light trapping (28%) in the MQW 22 with the conventional structure that does not include the anti-diffusion layer by about 3%. Here, the decrease in light trapping in the MQW by about 3% is considered to have a small influence on properties of the modulator.

As described above, it is possible to satisfactorily maintain the properties of the EA modulator if the thickness of the anti-diffusion layer is equal to or less than 400 nm, in terms of light trapping.

### Example 1

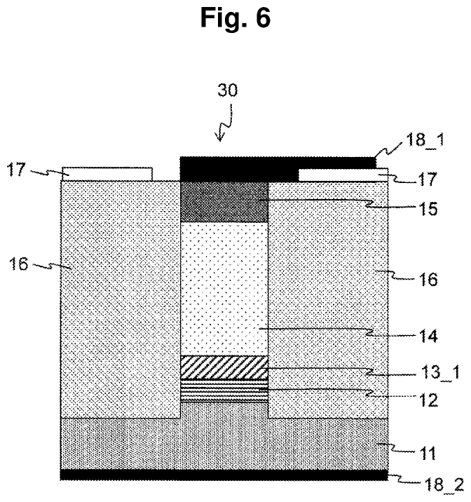

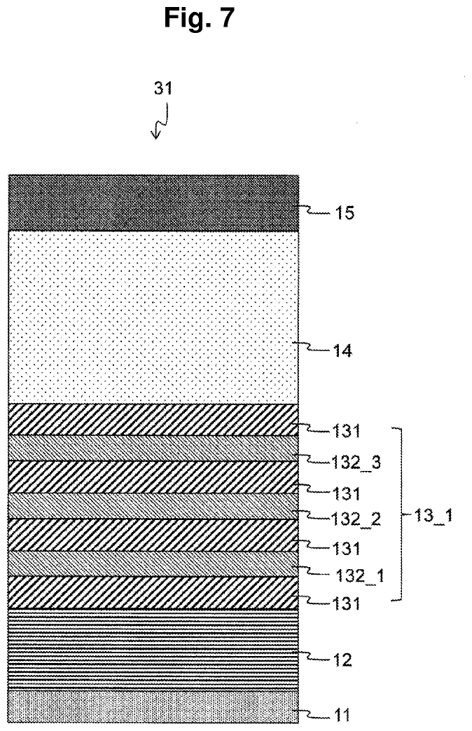

A semiconductor structure and a semiconductor element in Example 1 according to embodiments of the present invention will be described with reference to FIGS. 6 to 8.

### Configuration of Semiconductor Element

FIG. 6 illustrates a structure of a semiconductor element 30 in this example. The semiconductor element 30 is an EA modulator. The semiconductor element 30 includes a waveguide structure formed of a semiconductor structure 31 including an MQW 12, an anti-diffusion layer 13_1, a p-type InP cladding layer 14, and a p-type contact layer 15 laminated in order on an InP substrate 11, buried semi-insulating InP layers 16 on both side surfaces of the waveguide structure, an oxide film 17 on a front surface, and electrodes 18_1 and 18-2 on the front surface and the rear surface. Also, the device length of the semiconductor element 30 is 150 μm.

The MQW 12 includes eight InGaAlAs well layers (amount of strain: −0.5%, layer thickness: 10 nm) and nine InGaAlAs barrier layers (amount of strain: +0.3%, layer thickness: 6 nm), and the photoluminescence (PL) wavelength is 1.23 μm.

In the detailed semiconductor structure 31 in the waveguide structure, the anti-diffusion layer 13_1 has a structure in which a p-type InAlAs (thickness of 75 nm) 131, an i-type InGaAsP (thickness of 50 nm) 132_1, a p-type InAlAs (thickness of 75 nm) 131, an i-type InGaAsP (thickness of 30 nm) 131_2, a p-type InAlAs (thickness of 75 nm) 131, an i-type InGaAsP (thickness of 20 nm) 132_3, and a p-type InAlAs (thickness of 75 nm) 131 are laminated in order from the side of the MQW 12. The p-type InAlAs 131 is doped with C, and the C doping concentration is 3×10¹⁷ cm⁻³. Also, the i-type InGaAsP 132_1, 132_2, and 132_3 is undoped InGaAsP that has not been doped.

The p-type contact layer 15 is made of p-type InGaAs (thickness of 500 nm). The Zn doping concentration in the p-type contact layer 15 is 3 to 5×10¹⁸ cm⁻³.

### Effects of Semiconductor Element

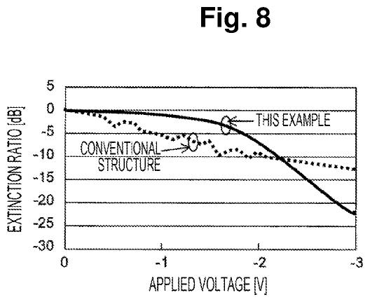

FIG. 8 illustrates an extinction property of the EA modulator in this example. As a comparative example, an extinction property of the conventional structure that does not include an anti-diffusion layer is also illustrated.

In the comparative example, the extinction ratio gradually decreases as the application voltage increases, and a steep extinction curve is not obtained (the dotted line in the drawing).

On the other hand, in the EA modulator in this example, a steep extinction curve is obtained when the application voltage is about −2 V, and a satisfactory extinction property is obtained (the solid line in the drawing). This is because diffusion of Zn to the MQW is curbed by the anti-diffusion layer.

Moreover, in the EA modulator in this example, i-type InGaAsP is applied to the anti-diffusion layer 13_1, and it is thus possible to curb a parasitic capacitance. As a result, it is possible to achieve 34 GHz as a 3 dB band, which is a property of the modulator. Also, it is possible to clear eye-pattern waveform with an extinction ratio of equal to or greater than 8.0 dB when the modulation amplitude voltage at the time of operating at 50 Gb/s is 1.5 V.

### Example 2

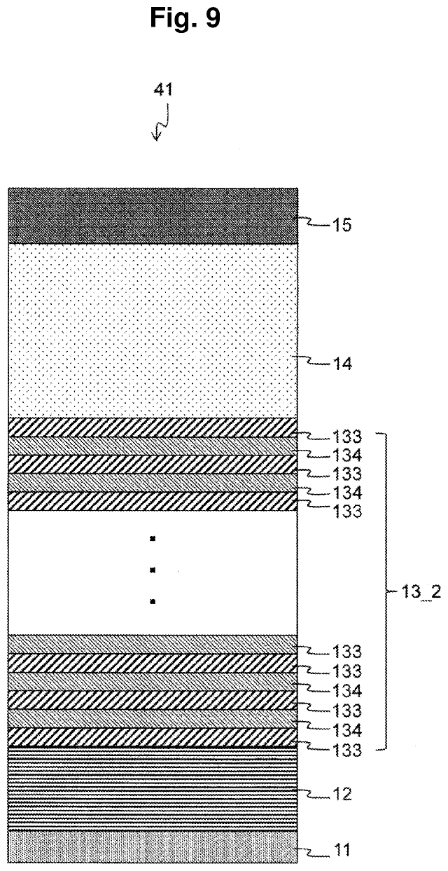

A semiconductor structure and a semiconductor element in Example 2 of embodiments of the present invention will be described with reference to FIG. 9.

### Configuration of Semiconductor Element

Although the configuration of the semiconductor element (EA modulator) in Example 2 is substantially similar to that in Example 1, configurations of the anti-diffusion layers are different.

An anti-diffusion layer 13_2 in the EA modulator in this example is a layer in which p-type InAlAs (thickness of 5 nm) 133 and p-type InGaAlAs (1.1 μm wavelength composition; thickness of 5 nm) 134 are alternately laminated and includes sixteen p-type InAlAs layers 133 and fifteen p-type InGaAlAs layers 134. The p-type InAlAs 133 is doped with C, and the C doping concentration is 3×10¹⁷ cm⁻³. Similarly, the p-type InGaAlAs 134 is doped with C, and the C doping concentration is 3×10¹⁷ cm⁻³.

### Effects of Semiconductor Element

In the EA modulator in this example, the layer thickness of the p-type anti-diffusion layer 13_2 is reduced, and it is thus possible to curb the parasitic capacitance. As a result, it is possible to achieve 34 GHz as a 3 dB band, which is a property of the modulator. Also, it is possible to clear eye-pattern waveform with an extinction ratio of equal to or greater than 8.0 dB when the modulation amplitude voltage at the time of operating at 50 Gb/s is 1.5 V.

Although the example in which the carbon (C) doping concentration in the anti-diffusion layer is 3×10¹⁷ cm⁻³ has been described in the embodiments and the examples of the embodiments of the present invention, the present invention is not limited thereto. It is desirable that the carbon (C) doping concentration in the anti-diffusion layer be equal to or greater than 1×10¹⁷ cm⁻³ and equal to or less than 1×10¹⁸ cm⁻³.

Although the example in which the layers including C-doped InAlAs and C-doped InGaAlAs or layers including C-doped InAlAs and undoped InGaAsP are used in the anti-diffusion layer has been described in the embodiments and the examples of the embodiments of the present invention, the present invention is not limited thereto. Layers including InGaAlAs with different compositions may be used. The anti-diffusion layer may be any anti-diffusion layer as long as it includes a plurality of layers that substantially lattice-match InP and at least one layer among the plurality of layers is a crystal containing Al, In, and As with p-type electric conductivity through doping with C. Here, the substantial lattice matching includes a case where InP match the number of lattices and complete lattice matching is established and also includes a state where crystal quality is not degraded in a state in which the crystal includes some strain even in a case where the InP is different from the number of lattices.

Although the n-type substrate is used as a substrate in the embodiments and the examples of the embodiments of the present invention, a p-type substrate may be used. In this case, a configuration in which a p-type substrate, an anti-diffusion layer, an MQW, an n-type cladding layer, and a contact layer are included in order is employed. Any configuration is adopted as long as the anti-diffusion layer is disposed between the p-type layer and the MQW.

Although the EA modulator has been described as an example of the semiconductor element in the embodiments of the present invention, the present invention is not limited thereto and can be applied to an optical semiconductor element in which the EA modulator is integrated, such as an EA modulator integrated distribution feedback (DFB) laser. Also, it is possible to apply embodiments of the present invention to other semiconductor elements as well, and it is possible to curb diffusion of Zn to an active layer (light emitting layer) by applying embodiments of the present invention to a semiconductor laser and thereby to realize laser properties such as a low threshold value and a high output.

Although examples of structures, dimensions, materials, and the like of the components have been described above in the configurations, the manufacturing methods, and the like of the semiconductor structure and the semiconductor element in the embodiments of the present invention, the present invention is not limited thereto. Any structures, dimensions, materials, and the like may be adopted as long as they exhibit the functions of the semiconductor structure and the semiconductor element.

### INDUSTRIAL APPLICABILITY

Embodiments of the present invention relate to an optical semiconductor element.

### REFERENCE SIGNS LIST

10 Semiconductor structure
11 InP substrate
12 Multi-quantum well (MQW)
13 Anti-diffusion layer
14 InP cladding layer
15 Contact layer

1.-8. (canceled)

9. A semiconductor structure comprising:
an InP substrate;
a multi-quantum well on the InP substrate;
an anti-diffusion layer on the multi-quantum well, wherein the anti-diffusion layer comprises a plurality of layers that lattice-match InP, and wherein a layer among the plurality of layers comprises Al, In, and As and is doped with carbon; and
a p-type InP layer on the anti-diffusion layer, wherein the p-type InP layer is doped with Zn.

10. The semiconductor structure according to claim 9, wherein a layer thickness of the anti-diffusion layer is equal to or greater than 50 nm and equal to or less than 400 nm.

11. The semiconductor structure according to claim 9, wherein the plurality of layers in the anti-diffusion layer comprises layers comprising InAlAs doped with the carbon alternatively laminated with layers comprising undoped InGaAsP.

12. The semiconductor structure according to claim 9, wherein the plurality of layers in the anti-diffusion layer comprises layers comprising InAlAs doped with the carbon alternately laminated with layers comprising InGaAlAs doped with the carbon.

13. The semiconductor structure according to claim 9, wherein a doping concentration of the carbon is equal to or greater than 1×10¹⁷ cm⁻³ and equal to or less than 1×10¹⁸ cm⁻³.

14. The semiconductor structure according to claim 9, wherein the InP substrate is an n-type InP substrate, and wherein the semiconductor structure further comprises a p-type contact layer on the p-type InP layer.

15. A semiconductor element comprising:
a waveguide structure comprising:
an InP substrate;
a multi-quantum well on the InP substrate;
an anti-diffusion layer on the multi-quantum well, wherein the anti-diffusion layer comprises a plurality of layers that lattice-match InP, and wherein a layer among the plurality of layers comprises Al, In, and As and is doped with carbon;
a p-type InP layer on the anti-diffusion layer; and
electrodes on a front surface and a rear surface of the waveguide structure.

16. The semiconductor element according to claim 15, wherein the semiconductor element comprises an electroabsorption-type modulator.

17. The semiconductor element according to claim 16, further comprising buried semi-insulating layers on both side surfaces of the waveguide structure.

18. The semiconductor element according to claim 17, wherein the buried semi-insulating layers comprise InP.

19. The semiconductor element according to claim 15, further comprising a p-type contact layer on the p-type InP layer, wherein the p-type contact layer is doped with Zn.

20. The semiconductor element according to claim 19, wherein the p-type contact layer comprises p-type InGaAs, and wherein a doping concentration of the Zn in the p-type contact layer is 3 to 5×10¹⁸ cm⁻³.

21. The semiconductor element according to claim 15, wherein the plurality of layers in the anti-diffusion layer comprises layers comprising InAlAs doped with the carbon alternatively laminated with layers comprising undoped InGaAsP.

22. The semiconductor element according to claim 15, wherein the plurality of layers in the anti-diffusion layer comprises layers comprising InAlAs doped with the carbon alternately laminated with layers comprising InGaAlAs doped with the carbon.

23. The semiconductor element according to claim 15, wherein a doping concentration of the carbon is equal to or greater than 1×10¹⁷ cm⁻³ and equal to or less than 1×10¹⁸ cm⁻³.

24. The semiconductor element according to claim 15, wherein the InP substrate is an n-type InP substrate, and wherein the waveguide structure further comprises a p-type contact layer on the p-type InP layer.
